(19) United States
(12) Patent Application Publication
(10) Pub. No.: US 2010/0139757 A1
(43) Pub. Date: Jun. 10, 2010

(54) PHOTOVOLTAIC CELL STRUCTURE

(75) Inventors: FENG FAN CHANG, KAOHSIUNG CITY (TW); HSIN CHIH LIN, TAICHUNG CITY (TW); HSIN HUNG LIN, YILAN COUNTY (TW); CHI HAU HSIEH, KAOHSIUNG CITY (TW); TZUNG ZONE LI, YUNLIN COUNTY (TW)

Correspondence Address: WPAT, PC;INTELLECTUAL PROPERTY ATTORNEYS, 2030 MAIN STREET, SUITE 1300, IRVINE, CA, 92614, US

(73) Assignee: RITDISPLAY CORPORATION, HSINCHU (TW)

(21) Appl. No.: 12/395,517

(22) Filed: Feb. 27, 2009

(30) Foreign Application Priority Data
Dec. 10, 2008 (TW) 097147950

(51) Int. Cl. H01L 31/00

(52) U.S. Cl. 136/256

(57) ABSTRACT

A photovoltaic cell structure includes a substrate, a metal layer, a high resistivity layer, a p-type semiconductor layer, an n-type semiconductor layer and a transparent conductive layer. The metal layer may include molybdenum and be formed on the substrate to be a back contact metal layer of the cell. The high resistivity layer (e.g., V₂O₅) is formed on the metal layer. The p-type semiconductor layer is formed on the high resistivity layer and may include compound of CIGS or CIS. The n-type semiconductor layer (e.g., CdS) is formed on the p-type semiconductor layer, thereby forming a p-n junction. The transparent conductive layer is formed on the n-type semiconductor layer.

### BACKGROUND OF THE INVENTION

(A) Field of the Invention

The present invention relates to a photovoltaic cell structure, and more specifically, to a thin-film photovoltaic cell structure including Copper Indium Gallium Diselenide (CIGS).

(B) Description of the Related Art

Normally, copper Indium Gallium Diselenide thin-film solar cells are one of two types; one is comprised of copper, indium and selenium, and another is comprised of copper, indium, gallium and selenium. Because of the high photoelectrical efficiency and low material cost, solar cell development is expected to continue at a rapid pace. The photoelectrical efficiency of CIGS solar cells in the laboratory can reach around 19%, and 13% for related solar cell modules.

FIG. 1 shows a traditional CIGS photovoltaic cell structure 10, which is a laminate structure. The photovoltaic cell structure 10 includes a substrate 11, a metal layer 12, a CIGS layer 13, a buffer layer 14 and a transparent conductive layer (TCO) 15. The substrate 11 may be a glass substrate, and the metal layer 12 may be a molybdenum metal layer to comply with the chemical characteristics of CIGS and withstand high temperature while the CIGS layer 13 is deposited. The CIGS layer 13 is a p-type semiconductor layer. The buffer layer 14, which is an n-type semiconductor layer that may be made of cadmium sulfate (CdS), and the CIGS layer 13 form a p-n junction therebetween. The transparent conductive layer 15 may be zinc oxide (ZnO) with doped aluminum (AZO) or the like. The transparent conductive layer 15 is also called a window layer, allowing light to penetrate through it and reach the CIGS layer 13 beneath it.

U.S. Pat. No. 6,258,620 disclosed a CIGS photovoltaic cell structure like that shown in FIG. 1, in which the transparent conductive layer 15 is AZO, and an intrinsic ZnO layer is formed between the transparent electrode 15 and the buffer layer 14. Because voids may occur in the crystal growth of CIGS, shorts can easily occur between the transparent conductive layer 15 serving as a cathode and the metal layer 12 serving as an anode of the cell. The intrinsic ZnO layer is of high resistivity to avoid short occurrence. However, because the intrinsic ZnO usually is formed by sputtering a ZnO target or by using physical vapor deposition (PVD) or chemical vapor deposition (CVD), and the voids may occur during CIGS crystal growth, the intrinsic ZnO has to be thick enough to avoid shorts. Therefore, the film formation mechanism of the intrinsic ZnO is complicated and requires lengthy formation time, so the throughput is not easily increased and the cost is difficult to reduce.

### SUMMARY OF THE INVENTION

The present invention provides a photovoltaic cell structure using a high resistivity layer to prevent electrical shorts between the transparent conductive layer (e.g., cathode) and the conductive metal layer (e.g., anode), and to increase throughput and reduce manufacturing material consumption.

In accordance with an embodiment of the present invention, a photovoltaic cell structure includes a substrate, a metal layer, a high resistivity layer, a p-type semiconductor layer, an n-type semiconductor layer and a transparent conductive layer. The metal layer may include vanadium and may be formed on the substrate to be a back contact metal layer of the cell. The high resistivity layer (e.g., V₂O₅) is formed on the metal layer. The p-type semiconductor layer is formed on the high resistivity layer and may include a compound of copper indium gallium selenium sulfur (CIGSS), copper indium gallium selenium (CIGS), copper indium sulfur (CIS), copper indium selenium (CIS) or a compound of at least two of copper, selenium or sulfur. The n-type semiconductor layer (e.g., CdS) is formed on the p-type semiconductor layer, thereby forming a p-n junction therebetween. The transparent conductive layer is formed on the n-type semiconductor layer.

The high resistivity layer can be very thin, e.g., 25 to 2000 angstroms, to avoid shorts between the cathode and anode of the cell. The manufacturing of the present invention is simple, fast and throughput can be easily increased.

### BRIEF DESCRIPTION OF THE DRAWINGS

FIG. 1 shows a known photovoltaic cell structure; and

FIG. 2 shows a photovoltaic cell structure in accordance with an embodiment of the present invention.

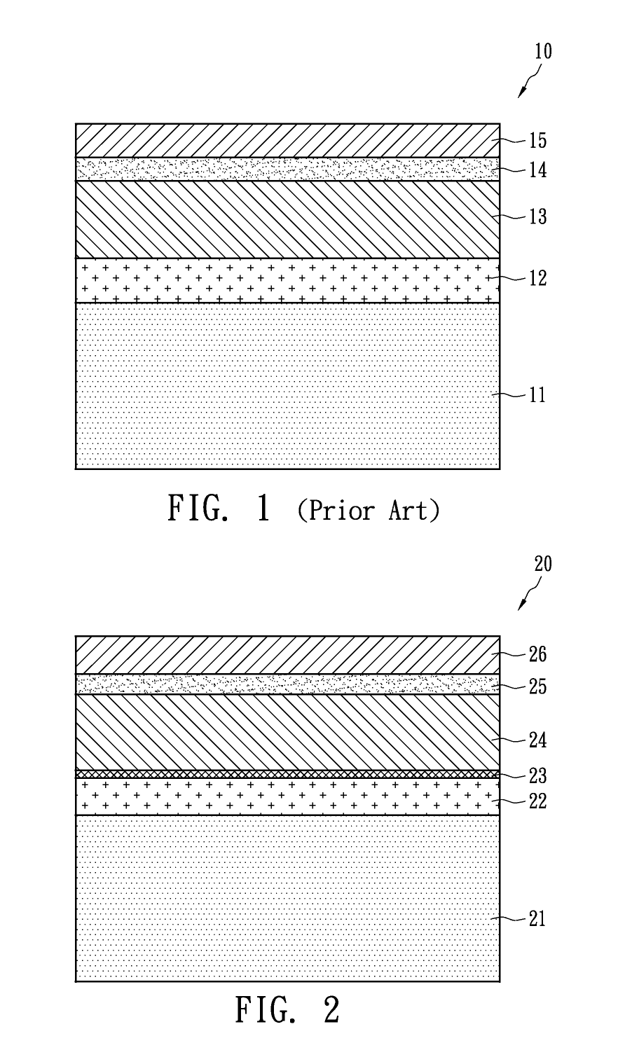

### DETAILED DESCRIPTION OF THE INVENTION

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

FIG. 2 shows a photovoltaic cell structure in accordance with an embodiment of the present invention. A photovoltaic cell structure 20 is a laminated structure and includes a substrate 21, a metal layer 22, a high resistivity layer 23, a p-type semiconductor layer 24, an n-type semiconductor layer 25 and a transparent conductive layer 26. In addition to a glass substrate, the substrate 21 may be a polyimide flexible substrate, or a metal plate or a metal foil of stainless steel, molybdenum, copper, titanium or aluminum. The substrate 21 is used for film formation and the shape thereof is not restricted to a plate; others such as a ball or specific or arbitrary shapes also can be used. The metal layer 22 may be a metal layer of molybdenum, chromium, vanadium or tungsten, and have a thickness between 0.5 to 1 micrometers. The metal layer 22 is formed on the substrate 21 to be a back contact metal layer of the cell. The high resistivity layer 23 (e.g., V₂O₅) is formed on the metal layer 22 and has a thickness between 25 and 2000 angstroms. The p-type semiconductor layer 24 is formed on the high resisitivity layer 23 and may include a compound of copper indium gallium selenium sulfur (CIGSS), copper indium gallium selenium (CIGS), copper indium sulfur (CIS), copper indium selenium (CIS) or a compound of at least two of copper, selenium or sulfur. The thickness of the p-type semiconductor layer 24 may be between 2 and 3 micrometers. The n-type semiconductor layer 25 is formed on the p-type semiconductor layer 24, thereby forming a p-n junction therebetween. In an embodiment, the n-type semiconductor layer 25 may be cadmium sulfate (CdS), zinc sulfate (ZnS) or indium sulfate (InS), and is much thinner than the p-type semiconductor layer 24, e.g., 0.05 micrometers, and has to be transparent, allowing sunlight to penetrate. The transparent conductive layer 26 is formed on the n-type semiconductor layer 25, and may be indium tin oxide (ITO), indium zinc oxide (IZO), aluminum zinc oxide (AZO), gallium zinc oxide (GZO), aluminum gallium zinc oxide (GAZO), cadmium tin oxide (CTO), zinc oxide (ZnO) and zirconium dioxide (ZrO₂) or other transparent conductive materials.

The metal layer 22 may be made of vanadium to comply with the chemical characteristics of CIS or CIGS and to withstand high temperature while the p-type semiconductor layer 24 (CIGS) is deposited. V₂O₅ exhibits high resistivity, so that it can be formed on the metal layer 22 as a carrier stop layer to avoid shorts.

As mentioned in the description of related art, the intrinsic ZnO layer for preventing shorts is conventionally formed by using physical sputtering. In sputtering, a ZnO target is bombarded with high energy and is ionized for film deposition. This process is complicated and is performed at a low temperature with a low deposition rate. Moreover, the intrinsic ZnO is a film to avoid shorts, and the surface of the CIGS layer is rough, so that the ZnO cannot be too thin and a thickness larger 600 angstroms is required; otherwise the prevention of shorts may be not effective. Moreover, ZnO film is difficult to be formed and is easily moisturized; the process control and device characteristics are limited.

According to the present invention, in contrast to the intrinsic ZnO layer, the high resistivity layer such as V₂O₅ can be formed by evaporation that is simple and can be performed at a high temperature to increase film deposition rate and throughput. In addition, the required thickness of a V₂O₅ layer, e.g., 25 to 2000 angstroms, is thinner than that of ZnO; thus in addition to the increase of process rate, the material consumption can be decreased. The thickness of the high resistivity layer between 25 and 2000 angstroms can effectively avoid shorts.

V₂O₅ is a p-type semiconductor, but other semiconductor compound of n-type or other insulation material having capacitive effect can also be used. In summary, the p-type or n-type semiconductor compound for the high resistivity layer 23 may be metal oxide or metal nitride. The metal oxide may be vanadium oxide, tungsten oxide, molybdenum oxide, copper oxide, iron oxide, tin oxide, titanium oxide, zinc oxide, zirconium oxide, lanthaium oxide, niobium oxide, indium tin oxide, strontium oxide, cadmium oxide, indium oxide or mixture or alloy thereof, and may further include insulation materials having capacitive effect such as silicon, aluminum oxide or the like.

In summary, the high resistivity layer 23 placed in the photovoltaic cell structure 20 can effectively prevent short occurrence between the metal layer 22 and the transparent conductive layer 26, and is thinner, thereby increasing throughput.

The above-described embodiments of the present invention are intended to be illustrative only. Numerous alternative embodiments may be devised by those skilled in the art without departing from the scope of the following claims.

What is claimed is:

1. A photovoltaic cell structure, comprising:
a substrate;
a metal layer formed on the substrate;
a high resistivity layer formed on the metal layer;
a p-type semiconductor layer formed on the high resistivity layer and comprising copper indium gallium selenium sulfur, copper indium gallium selenium, copper indium sulfur, copper indium selenium or comprising a compound of at least two of copper, selenium or sulfur;
an n-type semiconductor layer formed on the p-type semiconductor layer, thereby forming a p-n junction therebetween; and
a transparent conductive layer formed on the n-type semiconductor layer.

2. The photovoltaic cell structure of claim 1, wherein the high resistivity layer comprises metal oxide.

3. The photovoltaic cell structure of claim 2, wherein the metal oxide is selected from the group consisting of vanadium oxide, tungsten oxide, molybdenum oxide, copper oxide, iron oxide, tin oxide, titanium oxide, zinc oxide, zirconium oxide, lanthaium oxide, niobium oxide, indium tin oxide, strontium oxide, cadmium oxide, indium oxide or mixture or alloy thereof.

4. The photovoltaic cell structure of claim 1, wherein the high resistivity layer comprises insulation material having capacitive effect.

5. The photovoltaic cell structure of claim 4, wherein the insulation material is silicon or aluminum oxide.

6. The photovoltaic cell structure of claim 1, wherein the high resistivity layer comprises metal nitride.

7. The photovoltaic cell structure of claim 1, wherein the high resistivity layer has a thickness between 25 and 2000 angstroms.

8. The photovoltaic cell structure of claim 1, wherein the n-type semiconductor layer comprises cadmium sulfate, zinc sulfate or indium sulfate.

9. The photovoltaic cell structure of claim 1, wherein the transparent conductive layer comprises indium tin oxide, indium zinc oxide, aluminum zinc oxide, gallium zinc oxide, aluminum gallium zinc oxide, cadmium tin oxide, zinc oxide or zirconium dioxide.

10. The photovoltaic cell structure of claim 1, wherein the metal layer comprises molybdenum, chromium, vanadium and tungsten.

11. The photovoltaic cell structure of claim 1, wherein the substrate is a glass substrate, a polyimide flexible substrate, a metal plate or foil of stainless steel, molybdenum, copper, titanium or aluminum.
